(19) United States
(12) Patent Application Publication
(10) Pub. No.: US 2009/0202333 A1
(43) Pub. Date: Aug. 13, 2009

(54) ELECTRONIC COMPONENT PICKUP METHOD, ELECTRONIC COMPONENT MOUNTING METHOD AND ELECTRONIC COMPONENT MOUNTING APPARATUS

(75) Inventors: Mitsuru Ozono, Fukuoka (JP); Hiroshi Haji, Fukuoka (JP); Teruaki Kasai, Fukuoka (JP)

Correspondence Address: PEARNE & GORDON LLP, 1801 EAST 9TH STREET, SUITE 1200, CLEVELAND, OH, 44114-3108, US

(73) Assignee: MATSUSHITA ELECTRIC INDUSTRIAL CO., LTD., Osaka (JP)

(21) Appl. No.: 11/576,386

(22) PCT Filed: Oct. 4, 2005
(86) PCT No.: PCT/JP05/18332

§ 371 Date: Mar. 30, 2007

(30) Foreign Application Priority Data
Oct. 4, 2004 (JP) 2004-291239

(51) Int. Cl. H01L 21/673; H01L 21/677; H01L 21/67

(52) U.S. Cl. 414/800; 414/787

(57) ABSTRACT

This invention intends to provide an electronic component pick-up method, an electronic component loading method and an electronic component loading apparatus which are

capable of executing a pick-up operation of an electronic component adhesively held on a carrier stably and with high productivity.

In an electronic component pick-up method for picking up a chip 6 adhesively held by an adhesive layer 5a on a sheet 5, as the adhesive layer 5a, an adhesive containing a compound generating a nitrogen gas by application of ultraviolet rays is employed. In the pick-up operation, with a light applying unit 8 being located beneath the chip 6 to be picked up, ultraviolet rays is applied to the adhesive layer 5a located on the rear side of the chip 6 from the lower side of the sheet 5, and the chip 6 is picked up by bringing the holding tool 20 into contact with the upper surface of the chip 6 in a state where the nitrogen gas generated from the adhesive layer 5a has created a gaseous layer G between a bonding boundary between the rear surface of the chip 6 and the adhesive layer 5a.

### TECHNICAL FIELD

The present invention relates to a method for picking up an electronic component adhesively held on a carrier and a method and apparatus for loading the electronic component.

### BACKGROUND ART

A die bonding apparatus for mounting semiconductor chips cut down from a semiconductor wafer on a substrate such as a lead frame is provided with a pick-up device for peeling, from a sheet, an individual semiconductor chip which is adhesively held on the sheet serving as a carrier, and picking up it. In this pick-up device, as a technique for peeling the semiconductor chip in an adhered state from the sheet, a system using application of ultraviolet rays has become commercially practical in place of a thrust-up system using an ejector pin which was traditionally adopted (for example, Patent Reference 1). As an adhesive for causing the semiconductor chip to adhere on the sheet, this system employs the adhesive with a property that its adhesive force is reduced by application of ultraviolet rays. By applying ultraviolet rays in taking out the semiconductor chip, the adhesive force of holding the semiconductor chip on the sheet is reduced thereby to facilitate the pick-up of the semiconductor chip by an adsorption collet.

Patent Reference 1: JP-A-8-288318

### DISCLOSURE OF THE INVENTION

### Problems that the Invention is to Solve

However, the system disclosed in the above Patent Reference could not avoid variations in the effect of reducing the adhesive force by application of ultraviolet rays, which made it difficult to stably pick up the semiconductor chip. Particularly, for a thin semiconductor chip, it was difficult to prevent occurrence of damage such as cracking or chipping due to failure of a pick-up operation. Thus, sheet peeling by ultraviolet rays applying system could not be made practicable stably and with high productivity.

In view of the above circumstance, an object of the present invention is to provide an electronic component pick-up method, an electronic component loading method and an electronic component loading apparatus which are capable of stably picking up an electronic component adhesively held on a carrier.

### Means for Solving the Problems

The electronic component pick-up method according to the present invention is an electronic component pick-up method for picking up an electronic component adhesively held on the upper surface of a light permeable carrier by an adhesive substance generating a gas by light application, comprising: a light applying step of applying light to the adhesive substance located on the rear side of the electronic component to be picked up from the lower side of the carrier, thereby generating the gas from the adhesive substance; and a holding tool lifting/lowering step of bringing a holding tool into contact with the upper surface of the electronic component in the presence of the gas generated from the adhesive substance in the light applying step between the upper surface of the carrier and the rear surface of the electronic component and thereafter lifting the holding tool to pick up the semiconductor component.

The electronic component loading method according to the present invention is an electronic component loading method of picking up an electronic component adhesively held on the upper surface of a light permeable carrier by an adhesive substance generating a gas by light application, comprising: a light applying step of applying light to the adhesive substance located on the rear side of the electronic component to be picked up from the lower side of the carrier, thereby generating the gas from the adhesive substance; a holding tool lifting/lowering step of bringing a holding tool into contact with the upper surface of the electronic component in the presence of the gas generated from the adhesive substance in the light applying step between the upper surface of the carrier and the rear surface of the electronic component and thereafter lifting the holding tool to pick up the semiconductor component; an electronic component recognition step of recognizing the position of the electronic component picked up by the holing tool and held thereon; an electronic component alignment step of aligning the electronic component held on the holding tool with a substrate on the reflection of the recognition result in the electronic component recognition step; and an electronic component loading step of loading the electronic component thus aligned on the substrate.

The electronic component loading apparatus according to the present invention is an electronic component loading apparatus comprising: a component supplying stage for supporting a light permeable carrier with a plurality of electronic components adhesively held on its upper surface by an adhesive substance generating a gas by light application; a light applying unit for applying light to the adhesive substance located on the rear side of the electronic component to be picked up from the lower side of the carrier, thereby generating the gas from the adhesive substance; a relative movement mechanism for relatively moving the component supplying stage and the light applying unit, thereby aligning a light application range of the light applying unit with the lower surface of an electronic component to be picked up; a substrate holding stage for holding a substrate on which the electronic component is to be loaded; a holding tool for picking up and holding the electronic component on the carrier; a component loading mechanism for reciprocally moving the holding tool between the component supplying stage and the substrate holding stage so that the electronic components are loaded on the substrate; an electronic component recognition unit for recognizing the position of the electronic component on the holding tool; and a control section for controlling the operation of each of the light applying unit, the relative movement mechanism, the component loading mechanism and the electronic component recognition unit, wherein the control section causes the relative movement mechanism to execute an alignment step of locating the light applying unit beneath the electronic component to be picked up; causes the light applying unit to execute a light applying step of applying light to the adhesive substance located on the rear side of the electronic component from the lower side of the carrier, thereby generating the gas from the adhesive substance; causes the electronic component loading mechanism to execute a holding tool lifting/lowering step of bringing the holding tool into contact with the upper surface of the electronic component in the presence of the gas generated from the adhesive substance in the light applying step between the upper surface of the carrier and the rear surface of the electronic component and thereafter lifting the holding tool to pick up the semiconductor component; causes the electronic component recognition unit to execute an electronic component recognition step of recognizing the position of the electronic component picked up by the holing tool and held thereon; and causes the component loading mechanism to execute an electronic component alignment step of aligning the electronic component held on the holding tool with the substrate on the reflection of the recognition result in the electronic component recognition step and an electronic component loading step of loading the electronic component thus aligned on the substrate.

In accordance with the present invention, the electronic component is picked up by bringing the holding tool into contact with the upper surface of the electronic component in the presence of the gas, generated from the adhesive substance by light application to the adhesive substance located on the rear side of an electronic component to be picked up from the lower side of the carrier, between the upper surface of the carrier and the rear surface of the electronic component. The chip can be thereby easily peeled from the carrier. Thus, the pick-up operation of the electronic component adhesively held on the carrier can be executed stably and with high productivity.

### BRIEF DESCRIPTION OF THE DRAWINGS

FIG. 1 is a side view of an electronic component loading apparatus according to an embodiment of the present invention.

FIG. 2 is a block diagram showing the configuration of a control system of the electronic component loading apparatus according to an embodiment of the present invention.

FIG. 3 is an operation flow chart of an electronic component loading method according to an embodiment of the present invention.

FIG. 4 is a view for explaining operation timings in the electronic component pick-up apparatus according to an embodiment of the present invention.

FIG. 5 is a view for explaining the operation of the electronic component pick-up method according to an embodiment of the present invention.

FIG. 6 is a view for explaining the operation of the electronic component pick-up method according to an embodiment of the present invention.

FIG. 7 is a view for explaining the operation of the electronic component pick-up method according to an embodiment of the present invention.

FIG. 8 is a view for explaining the operation of the electronic component pick-up method according to an embodiment of the present invention.

FIG. 9 is a view for explaining the operation of the electronic component pick-up method according to an embodiment of the present invention.

### DESCRIPTION OF REFERENCE NUMERALS AND SIGNS

2 component supplying stage
5 sheet
5a adhesive layer
6 chip
7 light applying unit moving mechanism
8 light applying unit
10 substrate holding stage
12 substrate
13 second camera
16 first camera moving mechanism
17 first camera
18 component holding head moving mechanism
19 component holding head
20 holding tool

### BEST MODE OF CARRYING OUT THE INVENTION

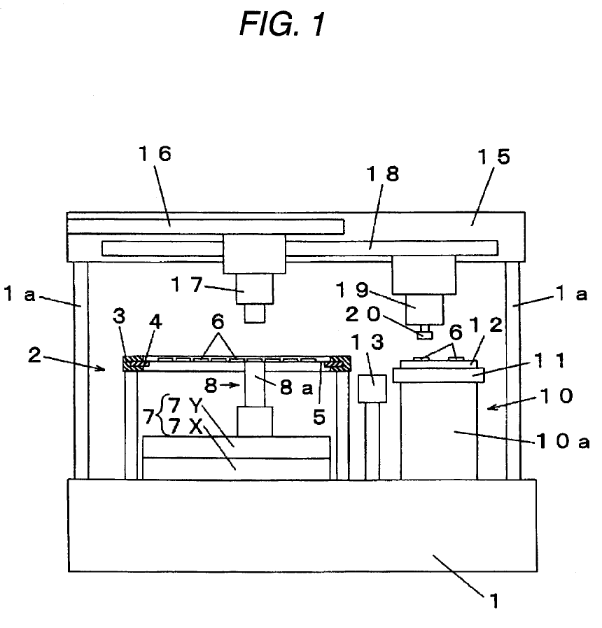

Next, referring to the drawings, an explanation will be given of an embodiment of the present invention. First, referring to FIG. 1, an explanation will be given of the structure of an electronic component loading apparatus. In FIG. 1, a component supplying stage 2 is arranged on a stand 1. The component supplying stage 2 has a jig holder 3 which detachably holds a jig 4 with a sheet 5 mounted therein. On the sheet 5, semiconductor chips 6 (hereinafter simply referred to as chips 6), which are electronic components, in a state separated in individual pieces.

The sheet 5 which is used as a carrier for the chips 6 is shaped in a sheet form from a light permeable material such as a transparent resin. On the upper surface of the sheet 5, formed is an adhesive layer 5a which is a thin film having an adhesive having the following property As the adhesive, used is an adhesive having the composition containing the compound having a property generating gas by light application (for example, an azide radical which is decomposed by application of ultraviolet rays to generate a nitrogen gas (see JP-A-2001-200234).

Specifically, the sheet 5 serves as a light-permeable carrier which adhesively holds a plurality of chips by the adhesive substance which generates gas by light application. The component supplying stage 2 supports the sheet 5 mounted in the jig 4 using the jig holder 3. In this way, by using, as the carrier holding the chips 6 through the adhesive layer 5a, such a sheet 5 having the adhesive layer 5a, as described later, the chips 6 can be easily peeled in picking up the chips 6 from the sheet 5.

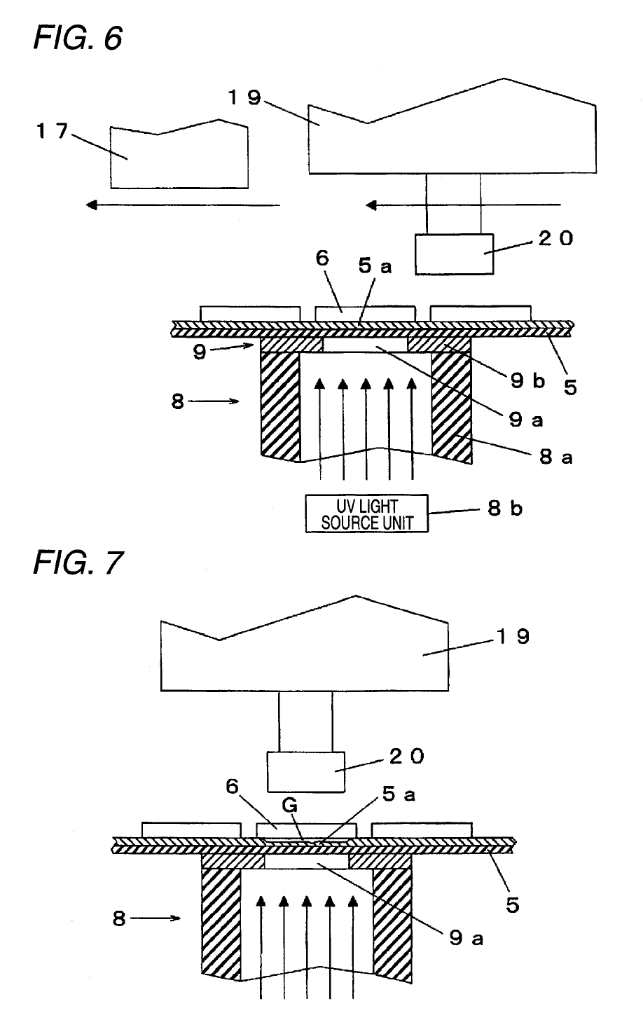

Beneath the sheet 5 held by the jig holder 3, a light applying unit 8 is arranged so as to be horizontally freely movable by a light applying unit moving mechanism 7 composed of an X-axis table 7X and a Y-axis table 7Y. The light applying unit 8 is provided with a cylindrical light conducting segment abutting on the lower surface of the sheet 5 and a UV light source segment 8b incorporated below the light conducting segment 8a (see FIG. 6). Ultraviolet rays projected upward from the UV light source segment 8b is applied to the lower of the sheet 5 via the interior of the light conducting segment 8a.

As seen from FIG. 6, on the upper surface of the light conducting segment 8a, mounted is an contact plate 9 having a structure in which the periphery of a light permeable body 9a at the center is surrounded by a light shading body 9b. Ultraviolet rays projected from the UV light source segment 8b permeates through the light permeable body 9a and is applied to the lower surface of the sheet 5. Now, the light permeable body 9a has such a size as limiting ultraviolet rays applying range to only one of the chips 6. Therefore, by aligning the light applying unit 8 with the chip 6 to be picked up, ultraviolet rays is applied to only the adhesive layer 5a located on the rear side of the chip 6.

In the pick-up operation of taking out the chip 6 from the component supplying stage 2, an alignment operation is carried out to horizontally move the light applying unit 8 by the light application moving unit 7 so that the light permeable body 9a is located immediately below the chip 6 to be picked up. In this state, the UV light source 8b is turned on to apply ultraviolet rays to the lower surface of the sheet 5 located immediately below the chip 6 to be picked up. Ultraviolet rays thereby permeates through the sheet 5 and is applied to the adhesive layer 5a so that a nitrogen gas is generated from the adhesive layer 5a. The nitrogen gas thus generated builds up at the bonding boundary between the chip 6 and the adhesive layer 5a to form a gaseous layer. Thus, the holding force of the adhesive layer 5a which adhesively holds the chip 6 is greatly lowered so that the chip 6 can be easily peeled from the sheet 5.

Namely, in the configuration described above, the light applying unit 8 has a function of generating the nitrogen gas from the adhesive layer 5a by applying ultraviolet rays from the lower side of the sheet 5 to the adhesive layer 5a located on the rear side of the chip 6 to be picked up. The light applying unit moving mechanism 7 serves as a relative movement mechanism for aligning the light applying range of the light applying unit 8 with the lower surface of the chip 6 to be picked up by moving the component supplying stage 2 and light applying unit 8 relatively to each other. Incidentally, by providing the light applying unit 8 with an adsorption mechanism for adsorbing/holding the sheet 5 from the rear side, the chip 6 can be more stably peeled from the sheet 5 as described later.

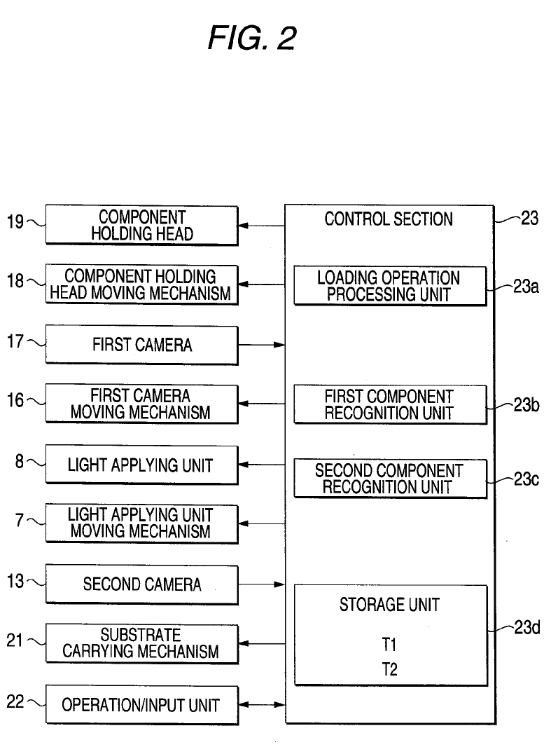

On the stand 1, arranged are a second camera 13 and a substrate holding stage 10 which are adjacent to the component supplying stage 2. The substrate holding stage 10 has a structure in which a substrate holding table 11 is placed on a base 10a. The substrate holding table 11 serves to hold a substrate 12 on which the chips 6 are to be loaded. Carry in/out of the substrate 12 for the substrate holding table 11 is performed by a substrate carrying mechanism 21 (see FIG. 2).

A horizontal upper frame 15 is laid over supporting posts la provided upright on both ends of the upper surface of the stand 1. On the upper frame 15, a first camera 17 is arranged so as to be horizontally movable by a first camera moving mechanism 16. The first camera 17 is moved by the first camera moving mechanism 16 so that the first camera 17 is located on any chip 6 held on the sheet 5 and image-picks up the chip 6. A first component recognition unit 23b (see FIG. 2) of a control section 23 recognition-processes the result of the image pick-up so that the position of any chip 6 is recognized.

On the upper frame 15, a component holding head 19 is arranged so as to be horizontally movable by a component holding head moving mechanism 18. A holding tool 20 is mounted below the component holding head 19. The component holding head 19 is moved to above the component supplying stage 2 and lowered with the holding tool 20 aligned with the chip 6 to be picked up. The holding tool 20 is thereby brought into contact with the upper surface of the chip 6 so that the chip 6 is held by vacuum adsorption.

The component holding head 19 having held the chip 6 by this pick-up operation is moved to above the substrate holding stage 10. Further, the holding tool 20 is lifted/lowered for the substrate 12 held on the substrate holding table 11 so that the chip 6 held on the holding tool 20 is loaded on the substrate 12. The component holding head moving mechanism 18 and component holding head 19 serve as a component loading mechanism which is provided with the holding tool 20 for picking up and holding the chip 6 on the sheet 5 and moved reciprocally between the component supplying stage 2 and substrate holding stage 10 to load the chip 6 on the substrate 12.

Below the moving path along which the component holding head 19 moves from the component supplying stage 2 to the substrate holding stage 10, a second camera 13 is arranged. The second camera 13 image-picks up the chip 6 held on the holding tool 20 from below. A second component recognition unit 23c recognition-processes the result of the image pick-up so that the position of the chip 6 being held on the holding tool 20 is recognized. In loading the chip 6 on the substrate 12 by the component holding head 19, on the reflection of this result of position recognition, the chip 6 is aligned with the substrate 12.

Next, referring to FIG. 2, an explanation will be given of the configuration of a control system. A control section 23 includes, as internal functions, a loading operation processing unit 23a, a first component recognition unit 23b, a second component recognition unit 23c and a storage unit 23d. The control section 23 controls the operation or processing in a component loading mechanism consisting of the component holding head 19 and component holding head moving mechanism 18, light applying unit 8, light applying unit moving mechanism 7 which is the relative movement mechanism and substrate carrying mechanism 21. An operation/input unit 22 is an input means such as a keyboard for inputting an operation command and various data such as time parameters T1, T2.

Now, the loading operation processing unit 23a controls each of the component holding head 19, component holding head moving mechanism 18, light applying unit 8, light applying unit moving mechanism 7 and substrate carrying mechanism 21 thereby to execute an electronic component loading operation described later. The first component recognition unit 23b recognition-processes the image pick-up result by the first camera 17 so that the position of the chip 6 held on the sheet 5 on the component supplying stage 2 is recognized. The second component recognition unit 23c recognition-processes the image pick-up result by the second camera 13 so that the position of the chip 6 being held by the component holding head 19 is recognized. The second camera 13 and second component recognition unit 23c serve as an electronic component recognition unit for recognizing the position of the chip 6 being held on the holding tool 20. In this way, the control section 23 controls the operation of each of the light applying unit 8, relative movement mechanism, component loading mechanism and electronic component recognition unit.

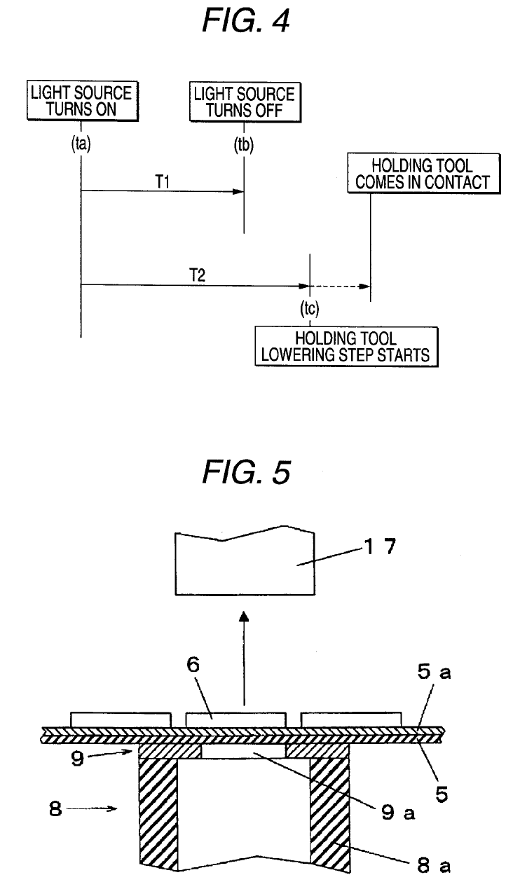

The storage unit 23d stores the time parameters T1, T2. The time parameters T1, T2 are set in order to realize the operation condition surely giving the effect of facilitating the peeling of the chip 6 in the electronic component loading operation described later. As seen from FIG. 4, the time parameter T1 indicates the time from the turn-on timing ta of the UV light source segment 8b to the turn-off timing tb thereof. Namely, the time enough to generate a sufficient amount of nitrogen gas from the adhesive layer 5a by U application is set as the time parameter T1. By appropriately setting the time parameter T1, waste of the operating time while the UV light source segment 8b remains on can be avoided.

The time parameter T2 indicates the time from the turn-on timing ta of the UV light source segment 8b to the timing tc of starting a holding tool lowering step. Namely, the time parameter T2 is set in expectation of that the timing of picking up the chip 6 on the sheet 5 by the holding tool 20 lies after the gaseous layer is sufficiently formed by the nitrogen gas generated. By appropriately setting the time parameter T2, the chip 6 can be picked up by the holding tool 20 after the gaseous layer with a sufficient size has been formed at the bonding boundary between the rear surface of the chip 6 and the adhesive layer 5a. Thus, the peeling promoting effect by the nitrogen gas can be assured when the chip 6 held by the holding tool 20 is peeled from the sheet 5. When a predetermined operating time required to lower the holding tool 20 elapses after the timing tc of starting the holding tool lowering step, the holding tool 20 comes into contact with the chip 6.

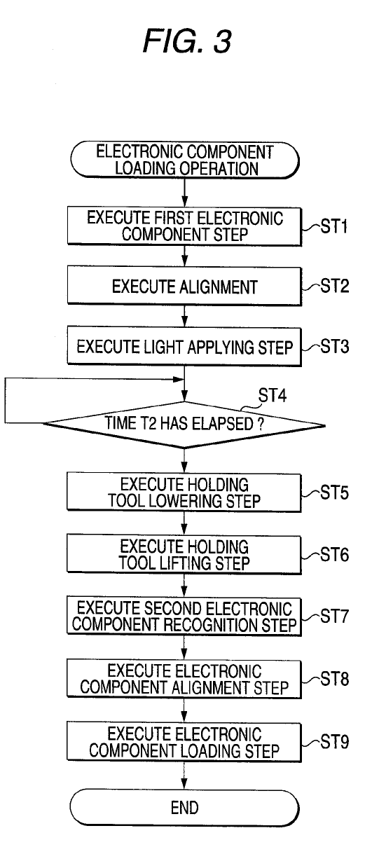

Next, referring to the respective drawings, an explanation will be given of an electronic component loading operation along the flowchart of FIG. 3. This electronic component loading operation is an electronic component loading method for picking up the chip 6 held by the holding tool 20 from the sheet 5, the chip 6 being adhesively held on the upper surface of the light permeable sheet 5 by the adhesive layer 5a which generates the nitrogen gas by UV application.

In FIG. 3, first, a first electronic component recognition step is executed (ST1). Specifically, as seen from FIG. 5, with the first camera 17 located above the chip 6 to be picked up, the chip 6 is image-picked up. The result of image pick-up is recognition-processed by the first component recognition unit 23b so that the position of the chip 6 is recognized. Incidentally, in this state, the light applying unit 8 is not properly aligned with the chip 6 to be picked up and the light permeable body 9a is deviated from the center of the chip 6.

Next, an alignment step is executed (ST2). Specifically, on the reflection of the recognition result in the first electronic component recognition step, the above position deviation is corrected and the light applying unit 8 is properly aligned below the chip 6 to be picked up. Thus, as seen from FIG. 6, the light permeable body 9a is located immediately below the chip 6. In this state, a light applying step is executed (ST3). Specifically, as seen from FIG. 6, the UV light source segment 8b is turned on to apply ultraviolet rays to the adhesive layer 5a located on the rear surface of the chip 6 to be picked up from the lower side of the sheet 5, thereby generating the nitrogen gas from the adhesive layer 5a. This light application is done continuously during only the predetermined time T1 previously set as the time parameter T1. In the meantime, the first camera 17 is retreated from above the chip 6 to be picked up and also the component holding head 19 is located above the chip 6.

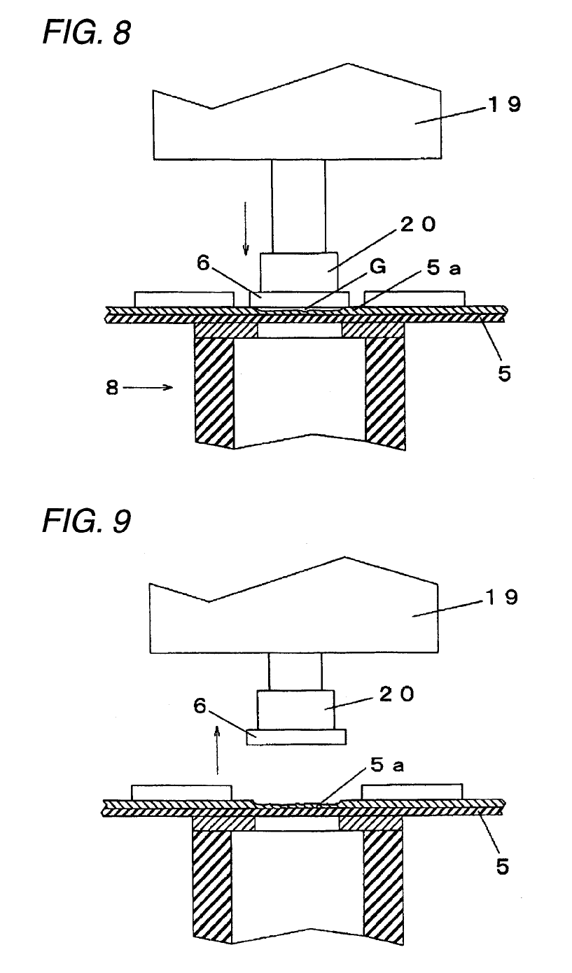

The elapse of the time T2 is monitored by a timer (ST4). By elapse of the predetermined time T2, if the nitrogen gas generated from the adhesive layer 5a builds up in a sufficient quantity at the bonding boundary between the chip 6 and the adhesive layer 5a so that a gaseous layer G is formed as seen from FIG. 7, a holding tool lowering step is executed (ST5). Specifically, as seen from FIG. 8, the holding tool 20 is lowered to come into contact with the upper surface of the chip 6, thereby holding the chip 6 by vacuum adsorption. Next, a holding tool lifting step is executed (ST6). Namely, the holding tool 20 as well as the chip 6 is lifted so that the chip 6 is picked up by its peeling from the sheet 5.

In other words, the above holding tool lowering step and holding tool lifting step correspond to a holding tool lifting/lowering step of bringing the holding tool 20 into contact with the upper surface of the chip 6 in the presence of the nitrogen gas generated from the adhesive layer 5a by the light applying step at the boundary between the upper surface of the sheet 5 and the rear surface of the chip 6 and thereafter lifting the holding tool 20 to pick up the chip 6. In the holding tool lowering step, after the predetermined time T2 elapses from the timing of starting light application in the light applying step as described above, the holding tool 20 is lowered. Thus, the holding tool lifting step can be executed at a high speed so that the speedup of the pick-up operation can be realized as a whole.

If the chip 6 has been picked up, the second electronic component recognition step is executed (ST7). Specifically, the component holding head 19 is moved to above the second camera 13. The chip 6 held on the holding tool 20 is image-picked up by the second camera 13. The result of image pick-up is recognition-processed so that the position of the chip 6 being held by the component holding head 19 is recognized. In the above light applying step, the nitrogen gas is generated before the holding tool 20 comes into contact with the chip 6. Therefore, the chip 6 may be shifted to generate position deviation. For this reason, in mounting the chip 6 on the substrate 12, the position of the chip 6 held on the holding tool 20 must be recognized.

Thereafter, the component holding head 19 is moved to the substrate holding stage 10 to execute an electronic component alignment step (ST8). On the reflection of the recognition result in the electronic component recognition step, the component holding head moving mechanism 18 is controlled to align the chip 6 held on the holding tool 20 with the substrate 12. Next, an electronic component loading step is executed (ST9) so that the chip 6 thus aligned is loaded on the substrate 12.

The control section 23, as described above, incorporates, as a function element, the loading operation processing unit 23a for controlling each of the component holding head 19, component holding head moving mechanism 18, light applying unit 8, light applying unit moving mechanism 7 and substrate carrying mechanism 21. The loading operation processing unit 23a controls the respective parts so that the following operation steps are executed. Thus, the electronic component loading device executes the above sequential electronic component loading operation.

More specifically, the light applying unit moving unit 7 is caused to execute the alignment step of locating the light applying unit 8 beneath the chip 6 to be picked up. The light applying unit 8 is caused to execute the light applying step of applying ultraviolet rays to the adhesive layer 5a on the rear surface of the chip 6 from the lower side of the sheet 5, thereby generating the nitrogen gas from the adhesive layer 5a. Further, the component loading mechanism consisting of the component holding head moving mechanism 18 and component holding head 19 is caused to execute the holding tool lifting/lowering step of bringing the holding tool 20 into contact with the upper surface of the chip 6 in the presence of the nitrogen gas generated from the adhesive layer 5a in the light applying step at the boundary between the upper surface of the sheet 5 and the rear surface of the chip 6 and thereafter lifting the holding tool 20 to pick up the chip 6.

Further, the electronic component recognition unit consisting of the second camera 13 and second component recognition unit 23c is caused to execute the electronic component recognition step of recognizing the position of the chip 6 picked up by the holding tool 20 and held thereon. The above component loading mechanism is caused to execute the electronic component alignment step of aligning the chip 6 held on the holding tool 20 with the substrate 12 on the reflection of the recognition result in the electronic component recognition step and to execute the electronic component loading step of loading the aligned chip 6 on the substrate 12.

The adoption of the configuration as described above can solve the problem of the conventional electronic component pick-up apparatus having the configuration in which the adhesive force of holding the semiconductor chip on the carrier is reduced by applying ultraviolet rays in picking up the semiconductor chip. Specifically, in the conventional apparatus, owing to the variation in the effect of reducing the adhesive force by the application of ultraviolet rays, it was difficult to stably execute the pick-up operation. Particularly, for a thin semiconductor chip, it was difficult to efficiently prevent occurrence of damage such as cracking or chipping due to failure of the pick-up operation.

On the other hand, in the electronic component pick-up apparatus proposed in this embodiment, by using the adhesive which generates the nitrogen gas by application of ultraviolet rays, the semiconductor chip can be taken out in the presence of the gaseous layer of the nitrogen gas at the boundary between the semiconductor chip and the sheet. Thus, the semiconductor chip can be peeled from the sheet easily and in a short time. Accordingly, without increasing the occurrence frequency of the inconvenience such as cracking or chipping of the semiconductor chip, the speedup of the pick-up operation of the semiconductor chip can be realized. As a result, the pick-up operation of the semiconductor chip adhesively held on the sheet can be performed stably and with high productivity.

The present invention has been explained in detail and referring to the specific embodiment. However, it is apparent to those skilled in the art that this invention can be changed or modified in various manners without departing from the spirit and scope of the invention.

The present application is based on Japanese Patent Application (Patent Application No. 2004-291239) filed on Oct. 4, 2004, and the contents thereof are incorporated herein by reference.

### INDUSTRIAL APPLICABILITY

The electronic component pick-up apparatus and method and electronic component loading apparatus give the effect of permitting the pick-up operation of the semiconductor chip adhesively held on the carrier to be performed stably and with high productivity and are useful to the use of picking up the electronic component held on an adhesive sheet in a die bonding apparatus and loading it on the substrate.

1. An electronic component pick-up method for picking up an electronic component adhesively held on the upper surface of a light permeable carrier by an adhesive substance generating a gas by light application, comprising:
a light applying step of applying light to the adhesive substance located on the rear side of the electronic component to be picked up from the lower side of said carrier, thereby generating the gas from said adhesive substance; and
a holding tool lifting/lowering step of bringing a holding tool into contact with the upper surface of the electronic component in the presence of the gas generated from said adhesive substance in said light applying step between the upper surface of the carrier and the rear surface of said electronic component and thereafter lifting said holding tool to pick up said semiconductor component.

2. An electronic component pick-up method according to claim 1, wherein said holding tool is lowered after a predetermined time elapses from a timing of starting light application in said light applying step.

3. An electronic component loading method for picking up an electronic component adhesively held on the upper surface of a light permeable carrier by an adhesive substance generating a gas by light application, comprising:
a light applying step of applying light to the adhesive substance located on the rear side of the electronic component to be picked up from the lower side of said carrier, thereby generating the gas from said adhesive substance;
a holding tool lifting/lowering step of bringing a holding tool into contact with the upper surface of the electronic component in the presence of the gas generated from said adhesive substance in said light applying step between the upper surface of the carrier and the rear surface of said electronic component and thereafter lifting said holding tool to pick up said semiconductor component;
an electronic component recognition step of recognizing the position of the electronic component picked up by said holing tool and held thereon;
an electronic component alignment step of aligning the electronic component held on said holding tool with a substrate on the reflection of the recognition result in said electronic component recognition step; and
an electronic component loading step of loading the electronic component thus aligned on said substrate.

4. An electronic component loading method according to claim 3, wherein said holding tool is lowered after a predetermined time elapses from a timing of starting light application in said light applying step.

5. An electronic component loading apparatus comprising:
a component supplying stage for supporting a light permeable carrier with a plurality of electronic components adhesively held on its upper surface by an adhesive substance generating a gas by light application;
a light applying unit for applying light to the adhesive substance located on the rear side of the electronic component to be picked up from the lower side of said carrier, thereby generating the gas from said adhesive substance;
a relative movement mechanism for relatively moving said component supplying stage and said light applying unit, thereby aligning a light application range of said light applying unit with the lower surface of an electronic component to be picked up;
a substrate holding stage for holding a substrate on which said electronic component is to be loaded;
a holding tool for picking up and holding the electronic component on said carrier;
a component loading mechanism for reciprocally moving said holding tool between said component supplying stage and said substrate holding stage so that the electronic components are loaded on said substrate;
an electronic component recognition unit for recognizing the position of the electronic component on said holding tool; and
a control section for controlling the operation of each of said light applying unit, said relative movement mechanism, said component loading mechanism and said electronic component recognition unit, wherein
said control section causes said relative movement mechanism to execute an alignment step of locating said light applying unit beneath the electronic component to be picked up; causes said light applying unit to execute a light applying step of applying light to the adhesive substance located on the rear side of the electronic component from the lower side of said carrier, thereby generating the gas from said adhesive substance; causes said electronic component loading mechanism to execute a holding tool lifting/lowering step of bringing the holding tool into contact with the upper surface of the electronic component in the presence of the gas generated from said adhesive substance in said light applying step between the upper surface of said carrier and the rear surface of said electronic component and thereafter lifting said holding tool to pick up said semiconductor component; causes said electronic component recognition unit to execute an electronic component recognition step of recognizing the position of the electronic component picked up by said holing tool and held thereon; and causes said component loading mechanism to execute an electronic component alignment step of aligning the electronic component held on said holding tool with the substrate on the reflection of the recognition result in said electronic component recognition step and an electronic component loading step of loading the electronic component thus aligned on said substrate.
